(19) United States
(12) Patent Application Publication
(10) Pub. No.: US 2026/0247761 A1
(43) Pub. Date: Aug. 20, 2026

(54) SEMICONDUCTOR STRUCTURE

(71) Applicant: Rayleigh Vision Intelligence Co., Ltd., Hsinchu City (TW)

(72) Inventor: Jr-Hau He, Hsinchu City (TW)

(21) Appl. No.: 19/176,195

(22) Filed: Apr. 11, 2025

(30) Foreign Application Priority Data
Feb. 20, 2025 (TW) 114106333

(51) Int. Cl. H10H 20/85; H10H 20/01

(52) U.S. Cl. CPC H10H 20/8508; H10H 20/017; H10H 20/018; H10H 20/019; H10H 20/036

(57) ABSTRACT

The present application provides a semiconductor structure, comprising a semiconductor component disposed on a light-transmitting substrate. The semiconductor component includes a semiconductor unit including a recess portion and a receiving portion disposed at an outer edge of the recess portion. An insulating layer covers an outside of the semiconductor unit, and includes a planar portion at an outside of the receiving portion. An electrode layer is electrically connected to the semiconductor unit and the light-transmitting substrate. The etched portion of the insulating layer forms the planar portion, and then the etched surface of the semiconductor unit forms the recess portion and the receiving portion on the semiconductor unit. The receiving portion is used to stably transfer the semiconductor structure in a line contact manner during transferring the semiconductor structure.

### FIELD OF THE INVENTION

The present application relates to a semiconductor structure, and more particularly to a device for connecting a semiconductor structure to a substrate in a line contact manner during a mass transfer process.

### BACKGROUND OF THE INVENTION

In prior art, the manufacturing processes and applications of chips includes a plurality of key processes, such as, the mass transfer process applied to Micro LED, which is an important step for transferring a large number of chips from the original substrate to the target substrate. However, the technical limitations of the chip structure design and the receiving method during the mass transfer process lead to positioning deviation and structural problems of chips during the mass transfer process, further affecting the quality and yield of the final product.

For example, in Micro LED process, the receiving surface of Micro LED chip during the mass transfer process is usually an entire epitaxial plane, that is, the bottom structure of the chip directly performing planar contacting during transferring to a substrate, which is a common practice in the prior art.

Using the epitaxial plane as the receiving surface usually requires the use of glue materials for fixation and support between the epitaxial plane and the target substrate. In the mass transfer process, the support method of the glue materials is surface support, that is, surface contacting with a large-area is formed between the glue material and the epitaxial plane. Although this support method can provide stable support in ideal conditions, in actual operation, it is easy to cause unstable stress on the receiving surface due to uneven external force distribution or deformation of the glue material.

When the glue material is under unstable stress during the mass transfer process, the chip may exhibit deviation and skewing on the target substrate. Especially in the context of mass transfer, due to the slight differences in the stress conditions of each chip on the glue material, the deviation problem may exhibit cumulative effects during the mass transfer process, leading to a decrease in the arrangement accuracy of the entire batch of chips. In addition, the skewing of the chip not only affects its arrangement on the target substrate, but also may adversely affect the reliability of the connection between the chip and subsequent circuits, ultimately leading to a decrease in product performance.

According to above, the well-known surface contacting has the problems of structural deviation and chip skewing during the transfer process. The problems not only reduce the stability of the Micro LED technology in the mass transfer process, but also bring significant challenges to the yield and performance of the final product. This has become a problem that restricts the further development and application of Micro LED technology, and it is an urgent problem to be solved in the industry.

In light of the aforementioned problems of the prior art, the present application provides a semiconductor structure, in which, after the semiconductor component is transferred onto the substrate, the upper surface of the semiconductor component is first etched to form a recess portion recessed and a receiving portion protruding on the semiconductor component.

### SUMMARY

An objective of the present application is to provide a semiconductor structure, in which, after the semiconductor component is transferred onto the substrate, the upper surface of the semiconductor component is first etched to form a recess portion and a protruding receiving portion on the semiconductor component. The receiving portion annularly disposed on the semiconductor unit is used to stably transfer the semiconductor structure in a line contact manner during the transfer of the semiconductor structure, thereby avoiding damage and skewing to the semiconductor structure.

To achieve the above-mentioned objects and effects, the present application provides a semiconductor structure, which comprises a light-transmitting substrate, a glue layer, and a semiconductor component. The glue layer is disposed on the light-transmitting substrate, and the semiconductor component is disposed on the glue layer. The semiconductor component comprises a semiconductor unit, an insulating layer and an electrode layer wherein the semiconductor unit includes a recess portion and a receiving portion, and the receiving portion is disposed on the outer edge of the recess portion disposed on the semiconductor unit; the insulating layer covers the outside of the semiconductor unit, and includes a planar portion on the outside of the receiving portion; the electrode layer passes through the insulating layer and is electrically connected to the semiconductor unit. The semiconductor unit, the insulating layer and the electrode layer are disposed on an epitaxial substrate, then the semiconductor component is transferred onto the upper side of the light-transmitting substrate and the glue layer for the insulating layer adhering on the glue layer, and part of the insulating layer is etched to form the planar portion on the outer edge of the semiconductor unit. Then, part of a surface of the semiconductor unit is etched to form the recess portion and the receiving portion on the surface of the semiconductor unit. With this structure for transferring the semiconductor structure, the semiconductor structure is stably transferred in a line contact manner during the mass transfer process, thereby, avoiding damage and skewing to the semiconductor structure.

In an embodiment of the present application, the semiconductor unit is a light emitting diode.

In an embodiment of the present application, the epitaxial substrate is a sapphire substrate.

In an embodiment of the present application, the semiconductor component is separated from the epitaxial substrate by a laser lift-off process.

In an embodiment of the present application, the insulating layer forms the protrusion portion on an upper portion of the epitaxial substrate, the protrusion portion is disposed on the upper outer edge of the semiconductor unit, when the semiconductor component is transferred onto the light-transmitting substrate and the glue layer, the protrusion portion is etched to form the planar portion on the upper outer edge of the semiconductor unit.

In an embodiment of the present application, the semiconductor component removes the protrusion portion of the insulating layer by an inductively coupled plasma etching or a reactive ion etching to form the planar portion.

In an embodiment of the present application, the part of the surface of the semiconductor unit is removed by an inductively coupled plasma etching or a reactive ion etching to form the recess portion.

In an embodiment of the present application, the receiving portion is annularly disposed on an upper side of the semiconductor unit.

In an embodiment of the present application, a material of the insulating layer is silicon nitride or silicon oxide.

In an embodiment of the present application, a thickness of the insulating layer is 500 nm^{~}1000 nm.

In an embodiment of the present application, a thickness of the glue layer is 0.1 μm^{~}10 μm, and the thickness of the glue layer is corresponding to an area of the semiconductor component.

In an embodiment of the present application, an absorption wavelength of the glue layer is from 200 nm to 400 nm.

### BRIEF DESCRIPTION OF THE DRAWINGS

FIG. 1 is a schematic diagram of the semiconductor structure according to an embodiment of the present application;

FIGS. 2A to 2F are schematic manufacturing diagrams of a planar portion according to an embodiment of the present application;

FIGS. 3A to 3B are schematic manufacturing diagrams of a receiving portion according to an embodiment of the present application; and

FIGS. 4A to 4B are schematic diagrams of a receiving portion for surface contacting according to an embodiment of the present application.

### DETAILED DESCRIPTION

To overcome the above problems of the prior art, the present application is to etch a semiconductor unit of a semiconductor component, so as to form a recess portion and a receiving portion on the semiconductor unit. The receiving portion annularly formed is used to stably transfer the semiconductor structure in a line contact manner during transferring the semiconductor structure. The problem of the prior art that the chip is damaged and skewed by surface contacting during the mass transfer process, resulting in improving of the issues in reduced yield and increased manufacturing cost.

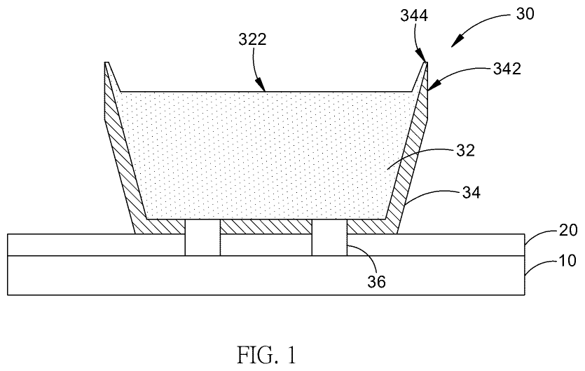

Referring to FIG. 1, which is a schematic diagram of the semiconductor structure according to an embodiment of the present application, as shown in the figure, this embodiment is the first embodiment to provide a semiconductor structure, comprising a light-transmitting substrate 10, a glue layer 20, and a semiconductor component 30.

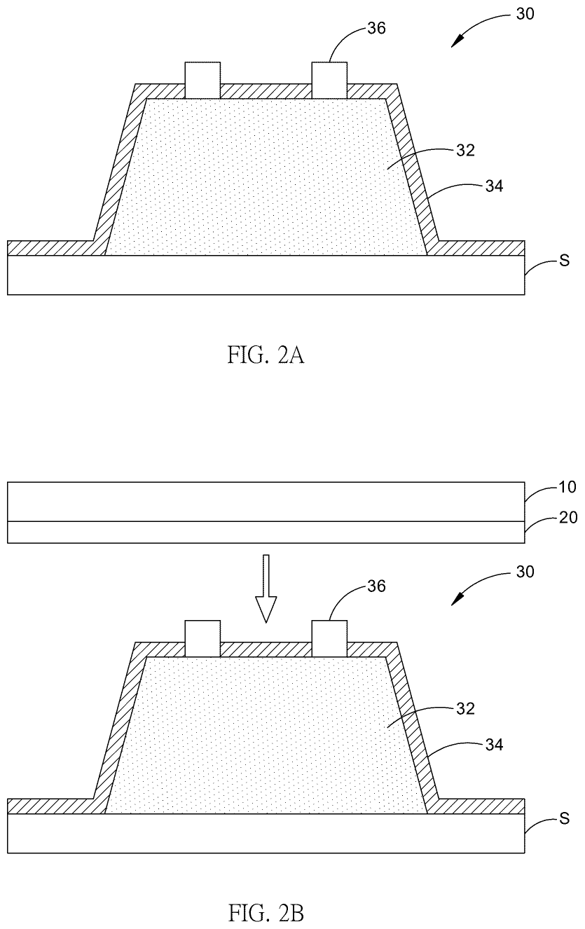

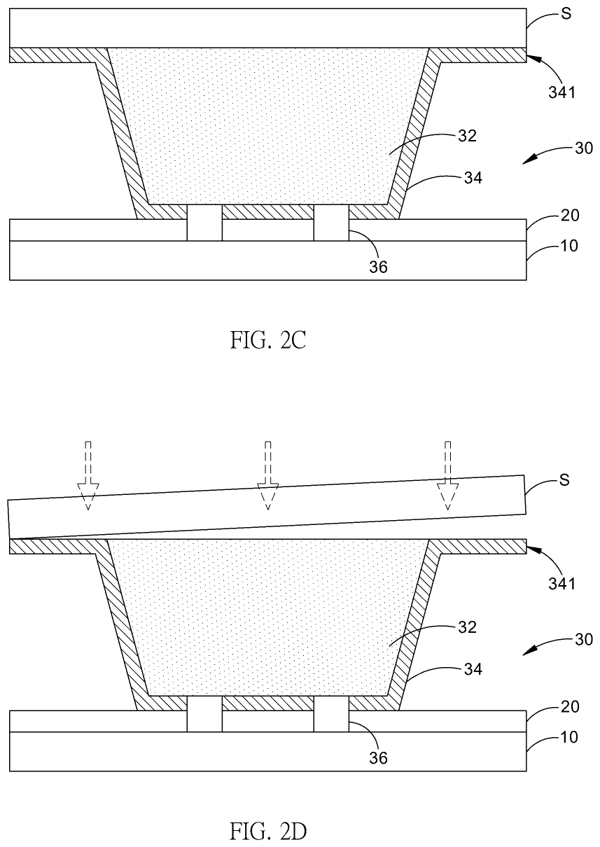

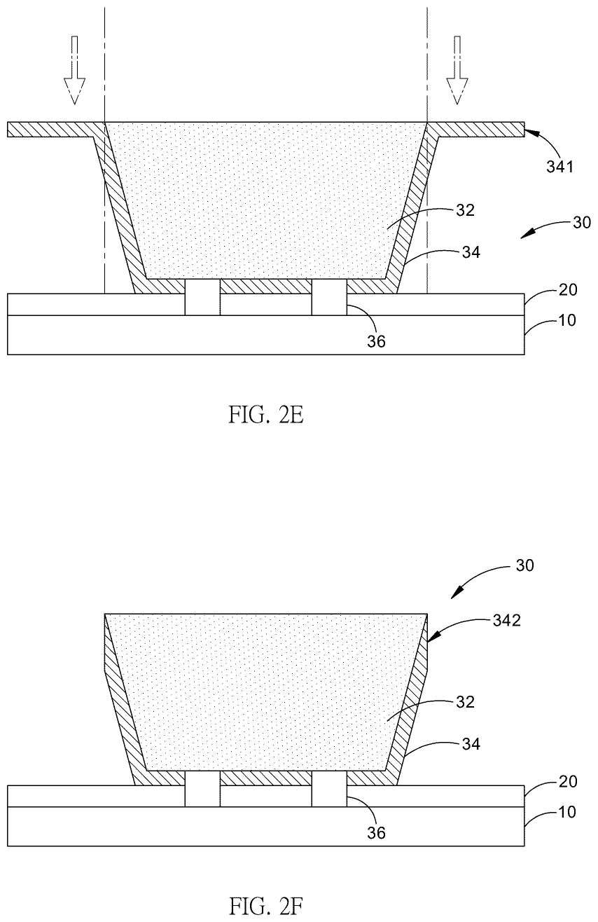

Referring to FIG. 1 again, and further referring to FIGS. 2A-2F, which are schematic manufacturing diagrams of a planar portion according to an embodiment of the present application, as shown in the figures, in this embodiment, the glue layer 20 is disposed on the light-transmitting substrate 10, and the semiconductor component 30 is disposed on the glue layer 20. The semiconductor component 30 comprises a semiconductor unit 32, an insulating layer 34, and an electrode layer 36. A recess portion 322 and a receiving portion 344 are disposed on the semiconductor unit 32. The receiving portion 344 is disposed on an outer edge of the recess portion 322. It should be noted that the receiving portion 344 is formed due to the formation of the recess portion 322. The insulating layer 34 covers an outside of the semiconductor unit 32, and a planar portion 342 is disposed on an upper outer edge of the semiconductor unit 32. The electrode layer 36 is electrically connected to and disposed under the semiconductor unit 32 while the electrode layer 36 passes through the insulating layer 34. The electrode layer 36 passes through the glue layer 20 and is electrically connected to the light-transmitting substrate 10.

Continuing with the above, as shown in FIG. 2A, during the manufacturing of the semiconductor component 30, the semiconductor unit 32, the insulating layer 34, and the electrode layer 36 of the semiconductor component 30 are disposed on an epitaxial substrate S, such as a sapphire substrate. After the semiconductor unit 32 and the electrode layer 36 of the semiconductor component 30 are formed on the epitaxial substrate S, the semiconductor unit 32 needs to be covered with an insulating material, namely, the insulating layer 34 covering the semiconductor unit 32, except for areas on the semiconductor unit 32 with the electrode layer 36. The insulating layer 34 is covered on the outside of the semiconductor unit 32 and the exposed surface of the epitaxial substrate S. Afterward, the electrode layer 36 of the semiconductor component 30 is exposed by the insulating layer 34.

As shown in FIG. 2B, after the semiconductor component 30 is formed the epitaxial substrate S, the light-transmitting substrate 10 and the glue layer 20 are moved toward the semiconductor component 30 and disposed on an end of the electrode layer 36 of the semiconductor component 30. As shown in FIG. 2C, the whole structure is flipped over after the glue layer 20 contacts the insulating layer 34 and the electrode layer 36 penetrates the glue layer 20 to electrically connect to the light-transmitting substrate 10. Afterward, the semiconductor component 30 is disposed on the glue layer 20 and the light-transmitting substrate 10, and the epitaxial substrate S is disposed on the semiconductor component 30. As shown in FIG. 2D, the epitaxial substrate S is removed by a laser lift-off process. After the epitaxial substrate S is removed, part of the insulation layer 34 originally formed on the surface of the epitaxial substrate S remains to form a protruding portion 341.

Continued with the above, the protrusion portion 341 is often a side skirt-shaped structure. During the subsequent transfer process, the protrusion portion 341 will be cracked due to external force generated by the mechanical bonding, peeling and alignment process. The cracked protrusion portion 341 will further damage the semiconductor structure and cause dark crack damage to the semiconductor component 30, thereby reducing the performance and life of the semiconductor structure.

Continued with the above, as shown in FIGS. 2E and 2F, in order to avoid the damage caused by the protruding portion 341 in the subsequent process, part of the insulation layer 34 is etched by inductively coupled plasma (ICP) or reactive ion etching (RIE), and the insulation layer 34 on the upper outer edge of the semiconductor unit 32 is removed to form a planar portion 342 on the upper outer edge of the semiconductor unit 32, namely, the protruding portion 341 is removed to form planar portion 342 on the upper outer edge of the semiconductor unit 32.

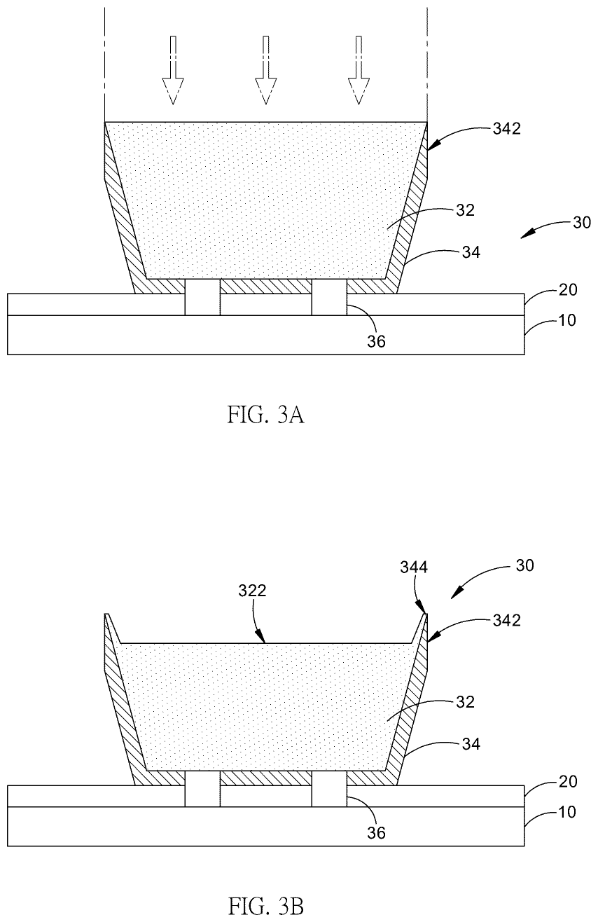

Referring to FIG. 1 again, and further referring to FIGS. 3A and 3B, FIGS. 3A and 3B, which are schematic manufacturing diagrams of a receiving portion according to an embodiment of the present application. As shown in the figures, in this embodiment, part of the upper surface of the semiconductor unit 32 is further etched by inductively coupled plasma (ICP) or reactive ion etching (RIE), so that the upper surface of the semiconductor unit 32 is recessed to form a recess portion 322. Due to the recess portion 322, the upper outer edge of the semiconductor unit 32 forms a receiving portion 344, which covers part of the insulation layer 34 at outside.

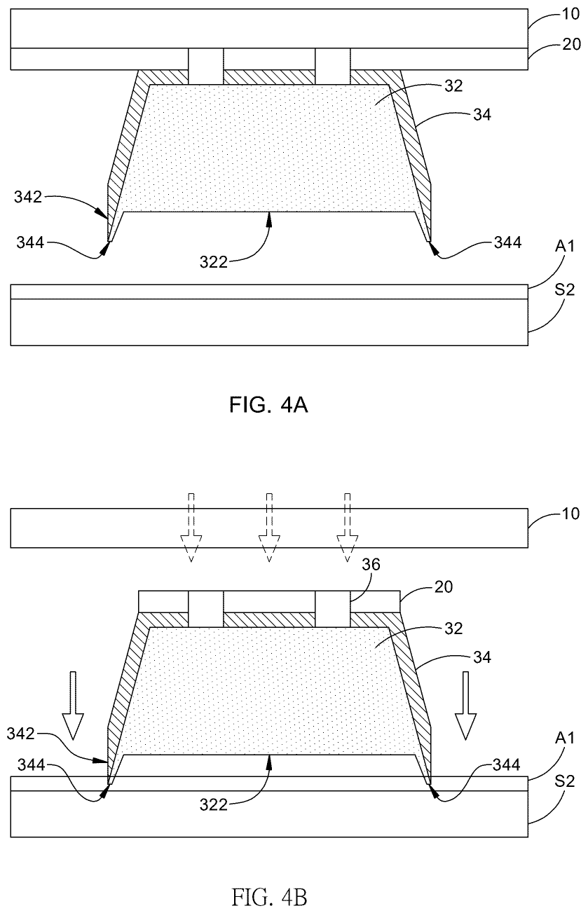

Referring to FIG. 4A and FIG. 4B, which are schematic diagrams of a receiving portion for surface contacting according to an embodiment of the present application. As shown in the figures, when the semiconductor component 30 needs to be transferred to another substrate S2, as shown in FIG. 4A, the whole structure is flipped over, and then, as shown in FIG. 4B, the light-transmitting substrate 10 is removed by the laser lift-off process. After the light-transmitting substrate 10 is removed, the semiconductor component 30 falls down, so that the receiving portion 344 of the semiconductor component 30 first contacts the another substrate S2 and another glue layer A1. Since the receiving portion 344 is annularly disposed on the surface of the semiconductor component 30, and the area of the receiving portion 344 is relatively small for line contact, the semiconductor component 30 can stably fall on another glue layer A1 of another substrate S2, avoiding the problem of the prior art in surface contacting without any moving space for the gas or glue layer contacting the central surface of the semiconductor component 30 to push the semiconductor component 30 and make the semiconductor component 30 be skewed.

According to above embodiments, Inductively Coupled Plasma (ICP) is a plasma generation technology based on electromagnetic induction, widely used in chemical analysis, material processing, and semiconductor manufacturing. Its principle is based on the alternating magnetic field generated by high-frequency alternating current in the induction coil, which realizes the ionization of gas and the stable maintenance of plasma by inducing the movement of electrons in the gas.

The generation process of inductively coupled plasma starts with the introduction of gas, such as argon. When high-frequency current passes through the induction coil, an alternating magnetic field is generated, which exerts force on the free electrons in the gas, causing them to move at high speed. These electrons collide with gas molecules or atoms, initiating a series of ionization processes and forming plasma. Due to the continuous action of the induced magnetic field, the electrons in the plasma are continuously accelerated, thereby maintaining a high-temperature stable plasma environment.

One of the main features of inductively coupled plasma is electrodeless design. Traditional plasma generation techniques often rely on direct contact electrodes, which can easily cause erosion of the electrode material, leading to impurity contamination. Inductively coupled plasma technology uses an inductive magnetic field for energy coupling, avoiding this problem and significantly improving the purity and stability of the plasma. In addition, inductively coupled plasma can generate extremely high plasma temperatures, making it effective in decomposing and exciting various substances in the sample.

In the above embodiments, reactive-ion etching (RIE) is a plasma etching technology widely used in semiconductor manufacturing and micro-nano processing fields, which combines chemical reactions and physical etching mechanisms to achieve precise selective removal of material surfaces. With its high directionality, high resolution, and excellent material compatibility, reactive-ion etching technology has become a key step in the production of fine structures in modern semiconductor processes.

The process principle of reactive-ion etching is based on the generation and control of plasma. In a reactive-ion etching system, specific gases (such as fluoride or chloride gases) are injected into the reaction chamber, and a high-frequency electric field is applied to the gases through a radio frequency power source, exciting the generation of plasma. The ions and free radicals in the plasma will undergo chemical reactions with the material surface, generating volatile by-products that are subsequently pumped away by the vacuum pump, thereby achieving material removal. In addition, electric field-driven ions will collide with the material surface in a highly directional manner, achieving physical etching and further enhancing the vertical directionality of the etching.

The combination of chemical reactions and physical etching is the core characteristic of reactive-ion etching. Chemical reactions provide high selectivity, allowing effective differentiation between etching targets and mask materials based on material characteristics and the choice of reaction gases. Physical etching brings excellent directionality, suitable for producing deep and narrow structural features such as transistor trenches, micro-electro-mechanical system (MEMS) structures, and fine patterns in optical devices.

The reactive ion etching technique has flexible process tunability. By adjusting the gas composition, gas pressure, RF power, and electrode bias, the reactive ion etching system can precisely control the etching rate, selectivity, and directionality. Different gases produce different reactive ions, suitable for processing different materials, for example, fluorine-based gases are commonly used for etching silicon, while chlorine-based gases are suitable for etching metals and compound semiconductors.

In above embodiments, the semiconductor device is exemplified by a light-emitting device, and the semiconductor component 30 may be a light-emitting component, and the semiconductor unit may be a light-emitting unit, such as a light-emitting diode.

In the above embodiments, a thickness of the glue layer 20 is 0.1 μm^{~}10 μm, the thickness of the glue layer 20 corresponding to the area of the semiconductor component 30 with better Lift-off effect as shown in following table.

Table the relationship between the thickness of the glue layer 20 and the area of the semiconductor component 30

| thickness of | area of semiconductor |
|---|---|
| glue layer (μm) | component (μm²) |
| 1~5 | <100 |
| 0.5~4 | 100~799 |
| 0.1~3 | 800~2000 |

This application is to provide the semiconductor structure with a respective thickness of the glue layer 20 corresponding to a respective area of the semiconductor component 30 for reducing the semiconductor component 30 in damage and offset flipping.

An absorption wavelength of the glue layer 20 is from 200 nm to 400 nm, for example, a material of the glue layer 20 is selected from a Laser Lift-off material or a Laser Debonding material, which commonly is a polyimide material or silicon oxide material, which is usually used to absorb the energy of the laser in 355 nm, even to absorb the energy of the laser in 248 nm or 266 nm.

Sum up, the present application provides a semiconductor structure, which is to transfer a semiconductor component from a epitaxial substrate to a light-transmitting substrate, etch the semiconductor unit of the semiconductor component to form a recess portion and a receiving portion on the semiconductor unit, and use the receiving portion annularly disposed on the semiconductor unit to stably transfer the semiconductor structure in a line contact manner during the transferring the semiconductor structure. This solves the problem of the prior art that the chip is damaged due to surface contact during the mass transfer process, which damages the light-emitting diode chip during the mass transfer process, resulting in a decrease in yield and an increase in manufacturing cost.

Therefore, the present application is undoubtedly novel, progressive, and applicable to the industry. Therefore, a patent application is submitted in accordance with that the patent will be granted as soon as possible.

The above description is only an embodiment of the present application and is not intended to limit the scope of the present application. Therefore, any equivalent changes and modifications made in accordance with the shape, structure, features, and spirit described in the patent application scope of the present application shall be included in the patent application scope of the present application.

What is claimed is:

1. A semiconductor structure, comprising:
a light-transmitting substrate;
a glue layer, disposed on the light-transmitting substrate; and
a semiconductor component, disposed on the glue layer, the semiconductor component comprising:
a semiconductor unit, having a recess portion and a receiving portion disposed on the semiconductor unit, the receiving portion being disposed on an outer edge of the recess portion;
an insulating layer, covering an outside of the semiconductor unit, and the insulating layer is provided with a planar portion on an outside of the receiving portion; and
an electrode layer, electrically connected and disposed below the semiconductor unit, the electrode layer penetrating through the insulating layer and electrically connecting the light-transmitting substrate;
wherein the semiconductor unit, the insulating layer and the electrode layer are disposed on an epitaxial substrate, then the semiconductor component is transferred to an upper side of the light-transmitting substrate and the glue layer while the insulating layer is adhered on the glue layer, and part of the insulating layer is etched to form the planar portion on an outer edge of the semiconductor unit, and a surface of the semiconductor unit is etched to form the recess portion and the receiving portion on the semiconductor unit.

2. The semiconductor structure of claim 1, wherein the semiconductor unit is a light-emitting diode.

3. The semiconductor structure of claim 1, wherein the epitaxial substrate is a sapphire substrate.

4. The semiconductor structure of claim 1, wherein the semiconductor component is separated from the epitaxial substrate by a laser lift-off process.

5. The semiconductor structure of claim 1, wherein the insulating layer forms the protrusion portion on the epitaxial substrate, and the protrusion portion is further disposed on the upper outer edge of the semiconductor unit, and when transferring the semiconductor component onto the light-transmitting substrate and the glue layer, the protrusion portion is etched to form the planar portion on the upper outer edge of the semiconductor unit.

6. The semiconductor structure of claim 1, wherein the protrusion portion of the insulating layer is removed by an inductively coupled plasma etching or a reactive ion etching to form the planar portion.

7. The semiconductor structure of claim 1, wherein the part of the surface of the semiconductor unit is removed by an inductively coupled plasma etching or a reactive ion etching to form the recess portion.

8. The semiconductor structure of claim 1, wherein the receiving portion is annularly disposed on the semiconductor unit.

9. The semiconductor structure of claim 1, wherein a material of the insulating layer is silicon nitride or silicon oxide.

10. The semiconductor structure of claim 1, wherein a thickness of the insulating layer is 500 nm to 1000 nm.

11. The semiconductor structure of claim 1, wherein a thickness of the glue layer is 0.1 μm^{~}10 μm, and the thickness of the glue layer is corresponding to an area of the semiconductor component.

12. The semiconductor structure of claim 1, wherein an absorption wavelength of the glue layer is from 200 nm to 400 nm.
